(19) United States
(12) Patent Application Publication
(10) Pub. No.: US 2008/0195817 A1
(43) Pub. Date: Aug. 14, 2008

(54) SD Flash Memory Card Manufacturing Using Rigid-Flex PCB

(75) Inventors: Siew S. Hiew, San Jose, CA (US); Nan Nan, San Jose, CA (US); Paul Hsueh, Concord, CA (US); I-Kang Yu, Palo Alto, CA (US); Abraham C. Ma, Fremont, CA (US)

Correspondence Address: BEVER HOFFMAN & HARMS, LLP;2099 Gateway Place, Suite 320, San Jose, CA, 95110, US

(73) Assignee: Super Talent Electronics, Inc., San Jose, CA (US)

(21) Appl. No.: 12/106,517

(22) Filed: Apr. 21, 2008

Related U.S. Application Data
(63) Continuation-in-part of application No. 10/888,282, filed on Jul. 8, 2004.
Application No. 10/888,282 is a continuation-in-part of application No. 11/773,830, filed on Jul. 5, 2007.
Application No. 11/773,830 is a continuation-in-part of application No. 11/309,594, filed on Aug. 28, 2006, now Pat. No. 7,383,362.
Application No. 11/309,594 is a continuation-in-part of application No. 10/913,868, filed on Aug. 6, 2004, now Pat. No. 7,264,992.

(51) Int. Cl. G06F 13/00; H05K 3/20

(52) U.S. Cl. 711/115; 29/831

(57) ABSTRACT

A memory card (e.g., SD or MMC) device including a PCBA in which components are mounted on a “rigid-flex” PCB including at least one rigid PCB section and at least one flexible PCB section, and a housing that includes both a pre-molded upper housing portion and a molded casing. The rigid-flex PCB is mounted into the upper housing portion such that standard metal contacts disposed on an upper surface of the rigid-flex PCB are exposed through openings defined the upper housing portion, and such that the flexible section of the rigid-flex PCB over any contours formed on the inside surface of the upper housing portion. The molded casing is then formed by depositing thermoset plastic over the lower surface of rigid-flex PCB.

### RELATED APPLICATIONS

This application is a continuation-in-part (CIP) of U.S. Patent application for “Manufacturing Method For Memory Card”, U.S. application Ser. No. 10/888,282, filed Jul. 8, 2004.

This application is a also a CIP of U.S. Patent application for “MOLDING METHODS TO MANUFACTURE SINGLE-CHIP CHIP-ON-BOARD USB DEVICE”, U.S. application Ser. No. 11/773,830, filed Jul. 5, 2007, which is a CIP of “Single-Chip Multi-Media Card/Secure Digital (MMC/SD) Controller Reading Power-On Boot Code from Integrated Flash Memory for User Storage”, U.S. application Ser. No. 11/309,594, filed Aug. 28, 2006.

This application is also a CIP of U.S. Patent application for “Removable Flash Integrated Memory Module Card and Method of Manufacture” U.S. application Ser. No. 10/913,868, filed Aug. 6, 2004.

### FIELD OF THE INVENTION

This invention relates to portable electronic devices, and more particularly to portable memory card devices such as those that utilize the Secure-Digital (SD) specification.

### BACKGROUND OF THE INVENTION

A card-type electronic apparatus containing a memory device (e.g., an electrically erasable programmable read-only memory (EEPROM) or “flash” memory chip) and other semiconductor components is referred to as a memory card. Typical memory cards include a printed circuit board assembly (PCBA) mounted or molded inside a protective housing or casing. The PCBA typically includes a printed circuit substrate (referred to herein simply as a “substrate”) formed using known printed circuit board fabrication techniques, with the memory device and additional components (e.g., control circuitry, resistors, capacitors, inductors, etc.) formed on an upper surface of the substrate (i.e., inside the casing), and one or more rows of contact pads exposed on a lower surface of the substrate. The contact pads are typically aligned in a width direction of the casing, and serve to electrically connect and transmit electrical signals between the memory chip/control circuitry and a card-hosting device (e.g., a computer circuit board or a digital camera). Examples of such portable memory cards include secure digital (SD) cards, multi media cards (MMC cards), personal computer memory card international association (PCMCIA) cards. An exemplary SD card form factor is 24 mm wide, 32 mm long, and 2.1 mm thick, and is substantially rectangular except for a chamfer formed in one corner, which defines the front end of the card that is inserted into a card-hosting device. The card's contact pads are exposed on its lower surface of each card near the front end. These and other similar card-like structures are collectively referred to herein as “memory module cards” or simply as “memory cards”.

An important aspect of most memory card structures is that they meet size specifications for a given memory card type. In particular, the size of the casing or housing, and more particularly the width and thickness (height) of the casing/housing, must be precisely formed so that the memory card can be received within a corresponding slot (or other docking structure) formed on an associated card-hosting device. For example, using the SD card specifications mentioned above, each SD card must meet the specified 24 mm width and 2.1 mm thickness specifications in order to be usable in devices that support this SD card type. That is, if the width/thickness specifications of a memory card are too small or too large, then the card can either fail to make the necessary contact pad-to-card-hosting device connections, or fail to fit within the corresponding slot of the associated card-hosting device.

Present SD memory card manufacturing is mainly implemented using standard surface-mount-technology (SMT) or chip-on-board (COB) manufacturing techniques, which are well known. The memory, controller and passive devices of each SD card device are typically mounted onto a rigid (e.g., FR or BT material) printed-circuit-board (PCB), which is then mounted inside of a pre-molded plastic housing.

Conventional production methods utilized to manufacture SD card devices present several problems.

First, using SMT methods alone to mount the various electronic components on the rigid PCB has the disadvantage of limiting the number of flash memory devices that can mounted on each SD device due to the thickness and width limitations on the SD card. That is, because the flash memory and controller chips have widths and thicknesses that are defined by the chip packaging dimensions, and because of the restrictions on total thickness of each SD card, only a limited number of packaged flash memory devices can be mounted inside each SD device using SMT methods. The space available for memory devices is further limited by the space needed for the pre-molded plastic housing, which is disposed on both sides of the PCBA. Further, even if room were available inside the housing, it would be too costly to stack “packaged” IC chips, and it would not be practical at present as SD flash card has it own standard shape and form.

Another possible approach to avoiding the vertical space limitations of SMT and pre-molded housings would be to use COB assembly methods to mount IC die onto a rigid PCB, and then using an over-molding process to form the housing. However, this over-molding method has the disadvantage of plastic flash spilling over the connector pins which causes poor electrical contact. Also, it is hard to mold multiple PCBA simultaneously using single molding process, which results in higher manufacturing costs.

What is needed is a method for producing memory cards that maximizes the amount of volume that can be used to house memory and control ICs, and avoids the problems mentioned above that are associated with conventional production methods.

### SUMMARY OF THE INVENTION

The present invention is directed to memory card (e.g., SD or MMC) devices including a PCBA in which components are mounted on a “rigid-flex” PCB including at least one rigid PCB section and at least one flexible PCB section, and a housing that includes both a pre-molded upper housing portion and a molded casing. The rigid-flex PCB is mounted into the upper housing portion such that standard metal contacts disposed on an upper surface of the rigid-flex PCB are exposed through openings defined the upper housing portion. In contrast to conventional single piece rigid PCBs, the rigid-flex PCB facilitates utilizing the entire interior housing space by positioning the flexible section of the rigid-flex PCB over any contours formed on the inside surface of the upper housing portion, thereby facilitating the production of devices that provide maximum package cavity space for accommodating larger memory capacities, e.g., by allowing multi-layer stacking of memory die to achieve high density memory device. The molded casing is then formed by depositing thermoset plastic over the lower surface of rigid-flex PCB such that the components are encased (i.e., substantially surrounded and held against the upper housing portion) by the thermoset plastic. The molded casing facilitates production of physically rigid (i.e., high impact resistant) memory cards that exhibit high moisture resistance by filling gaps and spaces around the components that are otherwise not filled when two pre-molded covers are used. The molded casing also enables the use of a wide range of memory devices by allowing the thermoplastic casing material formed over the memory device to be made extremely thin.

In accordance with a specific embodiment of the invention, the inside surface of the upper housing portion includes a step-like contour disposed between relatively thick ribs located near the front end, and a relatively upper wall, and the rigid-flex PCB includes two rigid PCB sections connected by an intervening flexible PCB section that extends over the step-like contour. The front (first) rigid PCB section is mounted on the lower surface of the ribs such that the standard metal contacts, which are formed on an upper surface of the front rigid PCB section, are exposed through openings defined between the ribs. The rear (second) rigid PCB section is mounted on the thin upper wall, whereby interior space located below the rear rigid PCB section is greater than the interior space located below the front rigid PCB section. The flexible PCB section extends over the contoured surface, thereby allowing the two rigid PCB sections to lie in the two different planes, thereby providing more interior space inside the housing than if a single rigid PCB were used, which would necessarily be positioned at the level of the front rigid PCB section.

In accordance with an embodiment of the present invention, a method for producing SD devices includes forming a PCB panel including multiple rigid-flex PCB regions arranged in rows and columns, and attaching at least one passive component and at least one integrated circuit to each rigid-flex PCB region. The PCB panel is then mounted onto a pre-molded, upper housing panel such that each rigid-flex PCB region is received inside a corresponding upper housing portion of the upper housing panel. The combined PCB panel and upper housing panel assembly is then mounted inside a molding cavity, and a thermal plastic material is molded over the passive component and integrated circuit to form the molded casing portion of the housing. Singulation is then performed to separate the individual SD devices from, e.g., the peripheral panel support structure and adjacent devices using a saw machine or other cutting device. Note that all three of the molded casing, upper housing material and the PCB material are cut during the same cutting process, whereby end edges of the rigid-flex PCB are exposed at each end of the finished device. This method facilitates the production of memory card devices at a lower cost and higher assembly throughput than that achieved using conventional production methods.

According to an aspect of the invention, passive components are mounted onto the PCB panel using one or more standard surface mount technology (SMT) techniques, and one or more integrated circuit (IC) die (e.g., an SD controller IC die and a flash memory die) are mounted using chip-on-board (COB) techniques. During the SMT process, the SMT-packaged passive components (e.g., capacitors and oscillators) are mounted onto contact pads disposed on each rigid-flex PCB of the PCB panel, and then known solder reflow techniques are utilized to connect leads of the passive components to the contact pads. During the subsequent COB process, the IC dies are secured onto the rigid-flex PCBs using known die-bonding techniques, and then electrically connected to corresponding contact pads using, e.g., known wire bonding techniques. After the COB process is completed, the housing is formed over the passive components and IC dies using plastic molding techniques. By combining SMT and COB manufacturing techniques to produce SD devices, the present invention provides an advantage over conventional manufacturing methods that utilize SMT techniques only in that overall manufacturing costs are reduced by utilizing unpackaged controllers and flash devices (i.e., by eliminating the cost associated with SMT-package normally provided on the controllers and flash devices). Moreover, the molded housing provides greater moisture and water resistance and higher impact force resistance than that achieved using conventional manufacturing methods. Therefore, the combined COB and SMT method according to the present invention provides a less expensive and higher quality (i.e., more reliable) memory product than that possible using conventional SMT-only manufacturing methods.

Various stacking arrangements of memory devices are facilitated according to additional alternative embodiments of the present invention, whereby the present invention facilitates the production of SD devices having a variety of storage capacities with minimal changes to the production process (i.e., simply changing the number of memory die layers changes the memory capacity).

Various rigid-flex PCBs are disclosed in accordance with alternative embodiments of the invention. In one embodiment, each rigid-flex PCB includes two rigid PCB sections that are connected by a flexible PCB section, wherein the rear rigid section is connected to lower side of the flexible PCB section, and the front rigid section is connected to upper side of flexible PCB section, thereby forming a step or stair-case type construction. In an alternative embodiment, both rigid PCB sections are connected to the upper side of the flexible PCB section rigid-flex PCB 111D, thereby forming an “in-line” construction. In another embodiment, a rigid-flex PCB panel includes only a short rigid PCB section connected to an elongated flexible PCB section on which the various components are mounted. In yet another alternative embodiment (not shown), instead of using a separate rigid PCB board structure (e.g., FR-4 or BT) to form the rigid PCB section, a stiffener (e.g., a polyimide stiffener) is added to the flexible cable used to construct flexible PCB section.

### BRIEF DESCRIPTION OF THE DRAWINGS

These and other features, aspects and advantages of the present invention will become better understood with regard to the following description, appended claims, and accompanying drawings, where:

FIG. 1 is a perspective top view showing an exemplary SD device according to an embodiment of the present invention;

FIG. 2 is a cross sectional side view showing the exemplary SD of FIG. 1;

FIG. 3 is a flow diagram showing a method for producing the SD device of FIG. 1 according to another embodiment of the present invention;

FIGS. 4(A) and 4(B) are bottom and top perspective views showing a PCB panel utilized in the method of FIG. 3 according to an embodiment of the present invention;

FIG. 5 is a perspective view depicting a surface mount technology (SMT) process for mounting passive components on a rigid-flex PCB according to the method of FIG. 3;

FIG. 6 is a top view showing the PCB panel of FIG. 4(B) after the SMT process is completed;

FIG. 7 is a simplified perspective view showing a semiconductor wafer including integrated circuits (ICs) utilized in the method of FIG. 3;

FIGS. 8(A), 8(B) and 8(C) are simplified cross-sectional side views depicting a process of grinding and dicing the wafer of FIG. 7 to produce IC dies;

FIG. 9 is a perspective view depicting a die bonding process utilized to mount the IC dies of FIG. 8(C) on a rigid-flex PCB according to the method of FIG. 3;

FIG. 10 is a top view showing the PCB panel of FIG. 6 after the die bonding process is completed;

FIG. 11 is a perspective view depicting a rigid-flex PCB of the PCB panel of FIG. 10 after a wire bonding process is performed to connect the IC dies of FIG. 8(C) to corresponding contact pads disposed on a PCB according to the method of FIG. 3;

FIG. 12 is a top view showing the PCB panel of FIG. 10 after the wire bonding process is completed;

FIG. 13 is perspective view showing a upper housing panel utilized in the method of FIG. 3;

FIG. 14 is a perspective view showing an assembly including the PCB panel of FIG. 12 mounted into the upper housing panel and rigid-flex PCB panel of FIG. 13 according to the method of FIG. 3;

FIGS. 15 is a perspective view showing the combined upper housing panel and PCB panel assembly of FIG. 13 into a lower molding die according to the method of FIG. 3;

FIGS. 16(A), 16(B) and 16(C) are simplified cross-sectional side views depicting subsequent steps of assembling the molding die and injecting molten plastic according to the method of FIG. 3;

FIG. 17 is a perspective bottom view showing the PCB panel of FIG. 12 after the plastic molding process of FIGS. 16(A) to 16(C) is completed;

FIG. 18 is a simplified cross-sectional side view showing the panel of FIG. 17 during a direct singulation process according to an embodiment of the present invention;

FIG. 19 is simplified top view showing process of marking the SD devices according to the method of FIG. 3;

FIGS. 20(A), 20(B), 20(C), 20(D), 20(E) and 20(F) are simplified cross-sectional side views showing a PCB panel during a stacked-device assembly process according to an alternative embodiment of the present invention;

FIG. 21 is a partial perspective view showing a portion of the PCB panel of FIG. 20(F) after the stacked-device assembly process of FIGS. 20(A) to 20(F) is completed;

FIGS. 22(A), 22(B) and 22(C) are cross-sectional side views showing various SD devices including different numbers of stacked memory devices according to alternative embodiments of the present invention;

FIG. 23 is a simplified cross-sectional side view showing a PCBA including a rigid-flex PCB panel according to an alternative embodiment of the present invention; and

FIG. 24 is a simplified cross-sectional side view showing a PCBA including a rigid-flex PCB panel according to another embodiment of the present invention.

### DETAILED DESCRIPTION OF THE DRAWINGS

The present invention relates to an improvement in manufacturing methods for SD (and MMC) devices, and to the improved SD devices made by these methods. The following description is presented to enable one of ordinary skill in the art to make and use the invention as provided in the context of a particular application and its requirements. As used herein, the terms “upper”, “upwards”, “lower”, “front”, “rear” and “downward” are intended to provide relative positions for purposes of description, and are not intended to designate an absolute frame of reference. Various modifications to the preferred embodiment will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

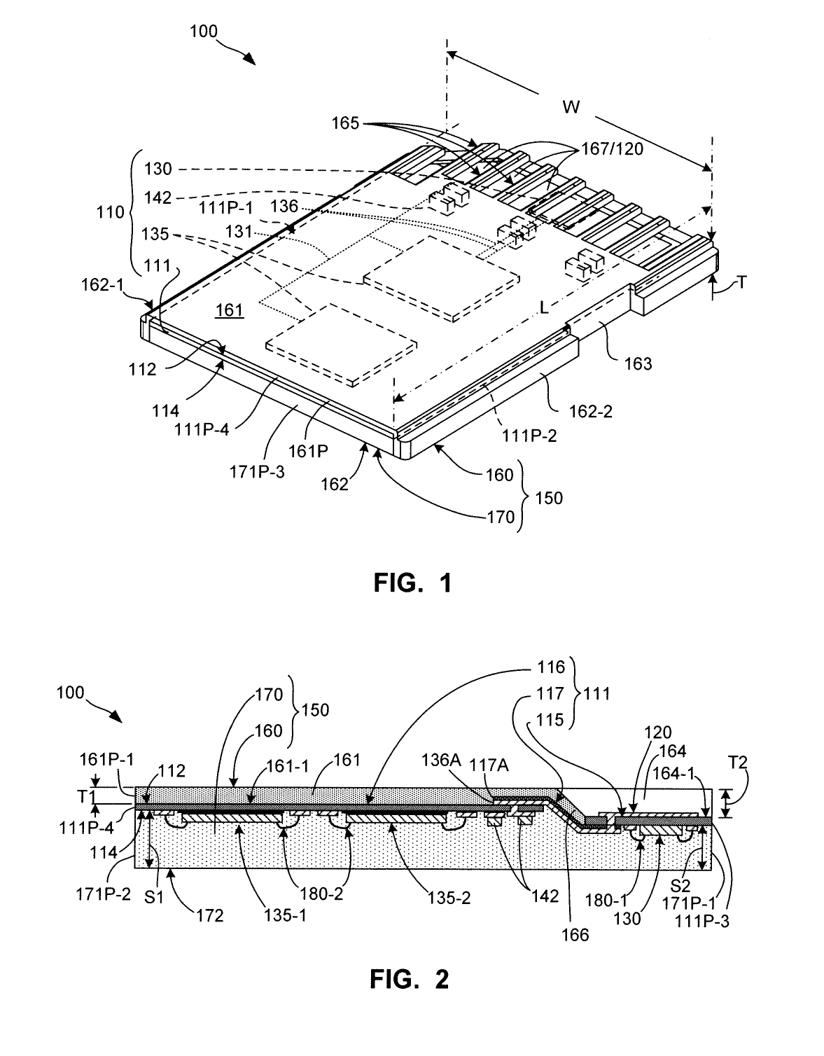

FIGS. 1 and 2 are perspective and cross-sectional side views showing a SD device 100 according to a first embodiment of the present invention. SD device 100 generally includes a printed circuit board assembly (PCBA) 110, and a housing 150 including a pre-molded upper housing portion 160 disposed against an upper (first) side 112 of PCBA 110 and a molded casing 170 that is formed on a lower (second) side 114 of PCBA 110. PCBA 110 includes a rigid-flex PCB 111 that includes nine standardized (plug) metal contacts 120 formed on upper surface 112 thereof, and several components, including IC dies 130 and 135 and passive components 142, which are attached to lower surface 114 of rigid-flex PCB 111. Metal contacts 120 are shaped and arranged in a pattern established by the SD specification, and are exposed through openings 167 defined by upper housing portion 160.

Referring to FIG. 2, according to an aspect of the present invention, rigid-flex PCB 111 includes one or more rigid PCB sections and one or more flexible PCB sections that are connected together such that at least some signals are transmitted over both the rigid and flexible sections of rigid-flex PCB 111. In the present embodiment, as shown in FIG. 2, rigid-flex PCBA 111 includes a front (first) rigid PCB section 115, a rear (second) rigid PCB section 116, and an intervening flexible PCB section 117 that is connected between rigid PCB sections 115 and 116. Rigid portions 115 and 117 are formed in accordance with known PCB manufacturing techniques such that metal contacts 120, IC dies 130 and 135, and passive components 142 are electrically interconnected by a predefined network including conductive traces 131 and 136 and other conducting structures that are sandwiched between multiple layers of an insulating material (e.g., a resin material such as FR-4 or Bismaleimide-Triazine (BT)) and adhesive. Rigid PCB sections 115 and 116 may also be formed by adding a polyimide stiffener to flexible cable to provide suitable stiffness of the active surfaces where connector gold fingers and passive components 142 are mounted, which require a still surface to perform the SMT procedure described below. In contrast to the rigid portions, flexible portion 117 is connected between rigid portions 115 and 116, and includes one or more polyimide (or other plastic or flexible non-conductive material) films 117A on which are formed conductive traces 136A (e.g., copper or another conductive material). In one embodiment, flexible portion 117 has a single-layer construction with a polyimide cover film laminated to copper allowing access to the copper from one side only. In another embodiment, flex cable 117 is double-sided copper clad material with top and bottom cover films. The cover films are pre-routed to access copper from both sides using plated thru holes. Opposing ends of flex cable 117 are respectively connected to rigid PCB 115 and rigid PCB 116 such that conductive traces 136A are electrically connected to corresponding conductive traces 131 and 136 formed on rigid PCB sections 115 and 116, thereby forming signal paths between rigid PCB sections 115 and 116 that extend over flexible PCB section 117.

According to an aspect of the invention, passive components are mounted onto surface 114 of rigid PCB section 116 using one or more standard surface mount technology (SMT) techniques, and one or more integrated circuit (IC) die (e.g., controller IC die 130 and flash memory dies 135-1 and 135-2) are mounted onto surfaces 114 of rigid PCB sections 115 and 116 using chip-on-board (COB) techniques. As indicated in FIG. 2, during the SMT process, the passive components 142, such as capacitors and inductors, are mounted onto contact pads (described below) disposed on surface 114, and are then secured to the contact pads using known solder reflow techniques. To facilitate the SMT process, each of the passive components is packaged in any of the multiple known (preferably lead-free) SMT packages (e.g., ball grid array (BGA) or thin small outline package (TSOP)). In contrast, IC dies 130, 135-1 and 135-2 are unpackaged, semiconductor “chips” that are mounted onto surface 114 and electrically connected to corresponding contact pads using known COB techniques. For example, as indicated in FIG. 2, control IC die 130 is electrically connected to rigid PCB section 115 by way of wire bonds 180-1 that are formed using known techniques. Similarly, flash memory IC dies 135-1 and 135-2 are electrically connected to rigid PCB section 116 by way of wire bonds 180-2. Passive components 142, IC dies 130 and 135 and metal contacts 120 are operably interconnected by way of metal traces 131 and 136 (depicted in FIG. 1 in a simplified manner by short dashed lines) that are formed on and in rigid PCB sections 115 and 116 and communicate by way of corresponding traces provided on flexible PCB section 117 using known techniques. Note that mounting controller IC die 130 on rigid PCB section 115 (i.e., on lower surface 114 opposite to metal contacts 120) provides additional space on rigid PCB section 116 for memory IC dies 135-1 and 135-2, thus facilitating larger memory dies and thus more memory capacity.

As indicated in FIG. 1, housing 150 has a length L, a width W and a front-end thickness T that are determined according to predetermined standards (e.g., SD or MMC standards). Upper housing portion 160 generally includes a substantially planar upper wall 161, side walls 162-1 and 162-2 extending downward from upper wall 161, and a series of ribs 165 extending from a front end of upper wall 161 and defining openings 167 therebetween. According to SD standards, side walls 162-1 and 162-2 define one or more notches (e.g., notch 163) that serve to house an optional write protect switch (not shown). Note that, for reasons that will become clear below, upper housing portion 160 does not include a rear wall, whereby a rear edge 161P of upper wall 161 is exposed. Note also that rigid-flex PCB 111 is mounted inside upper housing portion 160 such that side edges 111P-1 and 111P-2 of rigid-flex PCB 111 are covered by side walls 162-1 and 162-2, respectively, but that front edge 111P-3 (see FIG. 2) and rear edge 111P-4 are exposed. Molded casing 170 is disposed under rigid-flex PCB 111 such that substantially all of the plastic used to form molded casing 160 is located level with or below (i.e., on one side of) lower surface 114 of PCB substrate 111. The side edges of molded casing 170 are covered by side walls 162-1 and 162-2, but that a front edge 171P-1 (see FIG. 2) and a rear edge 171P-2 are exposed.

In accordance with an aspect of the present invention shown in FIG. 2, the inside surface of upper housing portion 160 includes a step-like contour 166 disposed between the relatively thick ribs 164 located near the front end, and the relatively upper wall 161, and flexible PCB section 117 is positioned to extend over step-like contour 166 to allow both rigid PCB sections 115 and 116 to lay flat and parallel to corresponding inside surfaces. Upper wall 161 has a first thickness T1, ribs 164 have a second thickness T2 that is greater than the first thickness T1, and a step-like contour surface 166 extends at an inclined angle between planar inside surface 161-1 of upper wall 161 and inside surfaces 164-1 of ribs 164. Referring to the right side of FIG. 2, front (first) rigid PCB section 115 is mounted on inside surface 164-1 of ribs 164 such that metal contacts 120 are exposed through openings 167 defined between ribs 164 (see FIG. 1). Similarly, rear (second) rigid PCB section 116 is mounted on planar inside surface 161-1 of relatively thin upper wall 161. Flexible PCB section 117 extends over contoured surface 166, thereby allowing the two rigid PCB sections 115,116 to lie in the two different planes, whereby interior space S1 located below rear rigid PCB section 116 is greater than interior space S2 located below front rigid PCB section 115, and thus providing more interior space inside housing 150 than if a single rigid PCB were used, which would necessarily generate narrower space S2 over the entire length of device 100.

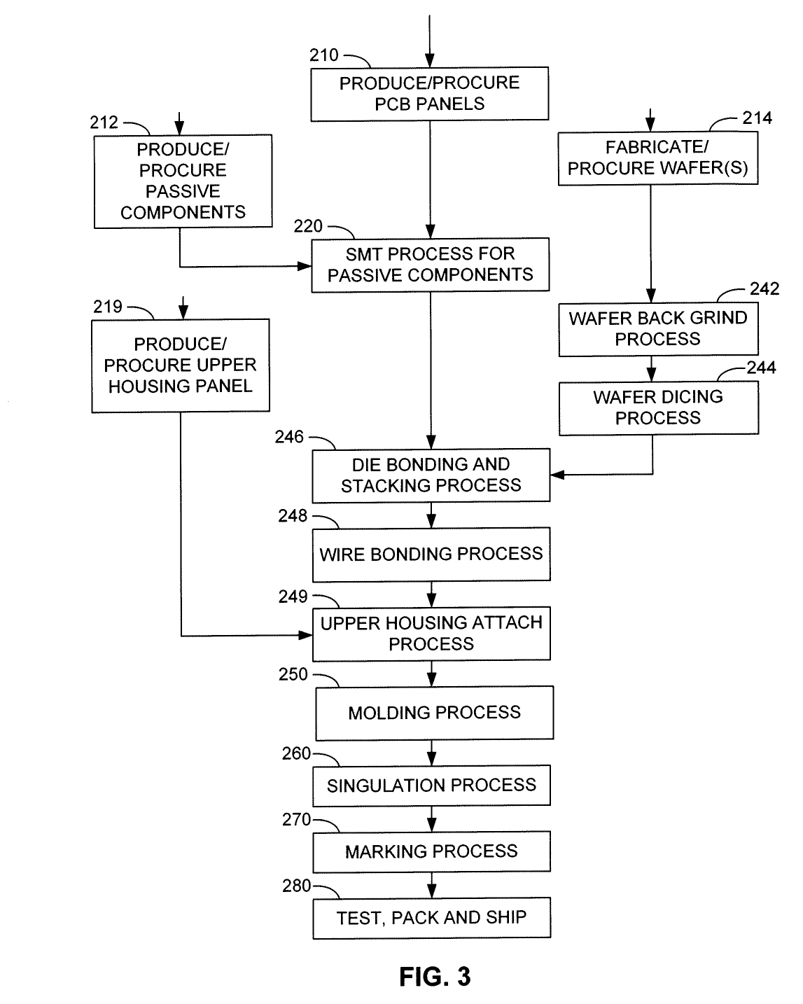

FIG. 3 is a flow diagram showing a method for producing SD devices 100 according to another embodiment of the present invention. Summarizing the novel method, a PCB panel is generated using known techniques (block 210), passive components are produced/procured (block 212), integrated circuit (IC) wafers are fabricated or procured (block 214), and one or more upper housing panels are produced or procured (block 219). The passive components are mounted on the PCB panel using SMT techniques (block 220), and the IC dies are subject to a grind-back process (block 242) and dicing process (block 244) before being die bonded (block 246) and wire bonded (block 248) onto the PCB panel using known COB techniques. The PCB panel is then mounted onto the upper housing panel such that each PCBA of the PCB panel is received inside a corresponding upper housing portion (block 249). Molten plastic is then used to form molded thermal plastic over the passive components and the IC dies (block 250). Then the PCB panel/upper housing panel assembly is singulated (cut) in to separate SD devices (block 260). The SD devices are then marked (block 270), and then the SD devices are tested, packed and shipped (block 280) according to customary practices.

The method for producing SD devices shown in FIG. 3 provides several advantages over conventional manufacturing methods. First, in comparison to methods that utilize SMT techniques only, by utilizing COB techniques to mount the SD controller and flash memory, the large amount of space typically taken up by the packages associated with these devices is dramatically reduced, thereby facilitating significant space. Second, by implementing the wafer grinding methods described below, the die height is greatly reduced, thereby facilitating a stacked memory arrangement that a significant memory capacity increase over packaged flash memory arrangements. The combination of pre-molded upper housing portion and molded upper housing portion also provides greater moisture and water resistance and higher impact force resistance than that achieved using conventional manufacturing methods, while avoiding the formation of thermoplastic material on metal contacts 120. In comparison to the standard SD memory card manufacturing that used SMT process, it is cheaper to use the combined COB and SMT (plus molding) processes described herein because, in the SMT-only manufacturing process, the bill of materials such as flash memory and the controller chip are also manufactured by COB process, so all the COB costs are already factored into the packaged memory chip and controller chip. Therefore, the combined COB and SMT method according to the present invention provides a less expensive and higher quality (i.e., more reliable) memory product with a smaller size than that possible using conventional SMT-only manufacturing methods.

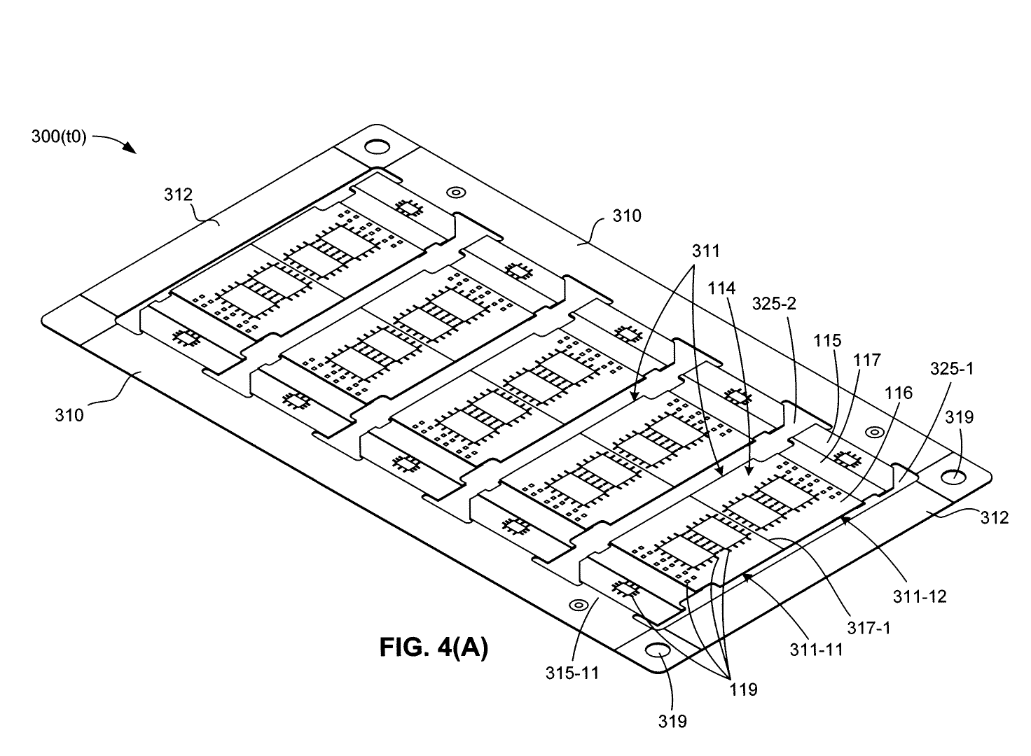

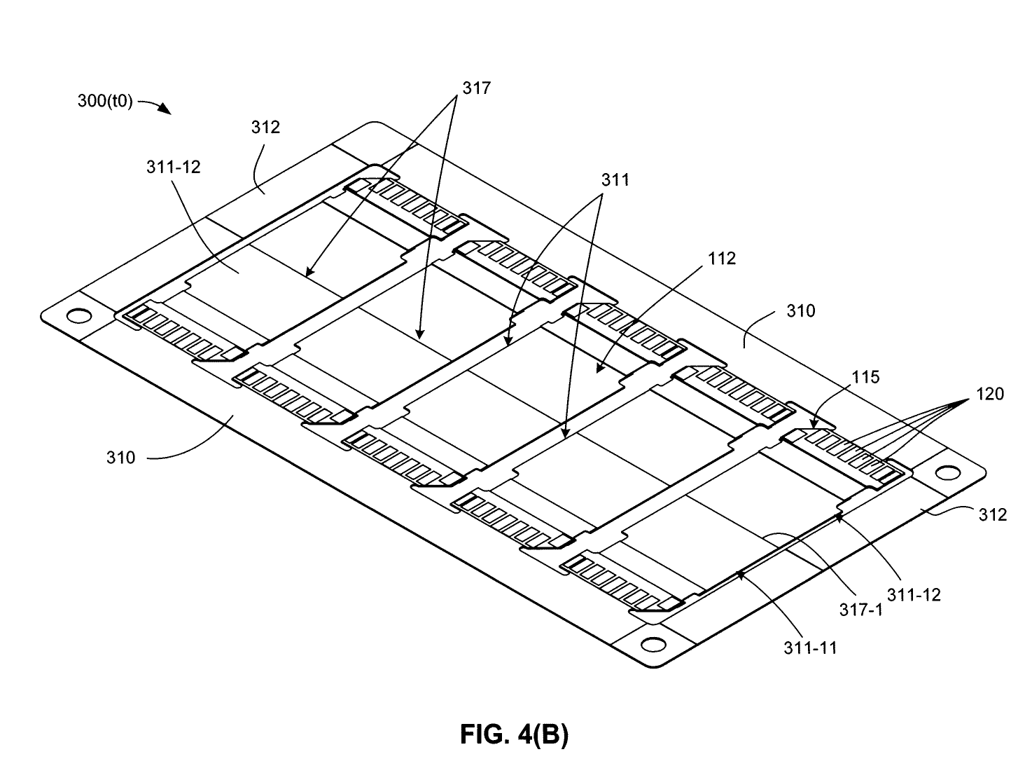

The flow diagram of FIG. 3 will now be described in additional detail below with reference to FIGS. 4(A) to 19.

Referring to the upper portion of FIG. 3, the manufacturing method begins with filling a bill of materials including producing/procuring PCB panels (block 210), producing/procuring passive (discrete) components (block 212) such as resistors, capacitors, diodes, and oscillators that are packaged for SMT processing, and producing/procuring a supply of IC wafers (or individual IC dies, block 214).

FIGS. 4(A) and 4(B) are simplified top and bottom views, respectively, showing a PCB panel 300(t0) provided in block 210 of FIG. 3 according to a specific embodiment of the present invention. The suffix “tx” is utilized herein to designated the state of the PCB panel during the manufacturing process, with “t0” designating an initial state. Sequentially higher numbered prefixes (e.g., “t1”, “t2” and “t3”) indicate that PCB panel 300 has undergone additional sequential production processes.

As indicated in FIG. 4(A) and 4(B), PCB panel 300(t0) includes a five-by-2 matrix of PCB regions 311 that are surrounded by opposing end border structures 310 and side border structures 312, which are integrally connected to form a square or rectangular frame of blank material around PCB regions 311. Each PCB region 311 (which corresponds to substrate 111; see FIG. 1) has the features described above with reference to FIGS. 1 and 2, and the additional features described below. FIG. 4(A) shows lower surface 114 of each PCB region 311, and FIG. 4(B) shows upper surface 112 of each PCB region 311, which includes standard metal contacts 120. Note that lower surface 114 of each PCB region 311 (e.g., PCB region 311-11) includes multiple contact pads 119 arranged in predetermined patterns for facilitating SMT and COB processes, as described below. Referring to FIG. 4(A), each PCB region 311 in each row is connected to an end border structure 310 and to an adjacent PCB region 311 by way of an intervening optional cut line 317. For example, referring to the lower row of PCBs in FIG. 4(A), PCB region 311-11 is connected to the left end border structure 310 by way of PCB end region 315-11, and by intervening optional cut line 317-1 to adjacent PCB region 311-12. As described above and indicated with reference to PCB region 311-12, each PCB region includes a front rigid PCB section 115, a rear rigid PCB section 116, and an intervening flexible PCB section 117. In accordance with an aspect of the present invention, optional designated cut lines 317 are scored or otherwise partially cut into one of side border structure 312 and/or central region of PCB panel 300 that are aligned with the front and rear edges of PCB regions 311 aligned in each row and column, respectively. In an alternative embodiment, cut lines 317 may be omitted, or comprise surface markings that do not weaken the panel material. Note that side edges of each PCB region 311 are exposed by elongated slots (openings) that extend between end border regions 310. For example, side edges of PCB sections 311-11 and 311-12 are exposed by elongated punched-out slots (lanes) 325-1 and 325-2. FIG. 4(B) shows upper side 112 of PCB regions 311 of PCB panel 300, and shows that metal contacts 120 are formed on front rigid PCB section 115 of each PCB regions 311 (e.g., PCB region 311-12).

In accordance with yet another aspect of the present invention, border structures 310 and 312 are provided with positioning holes 319 to facilitate alignment between PCB panel 300 and the plastic molding die during molded housing formation, as described below.

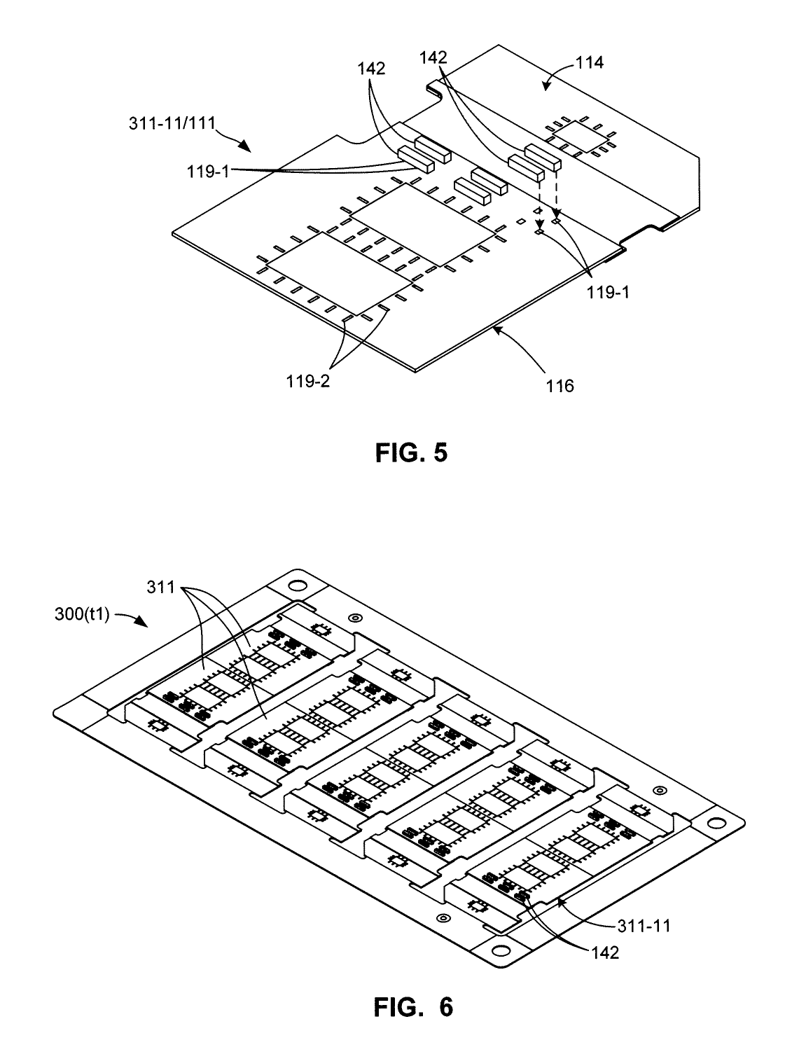

FIG. 5 is a perspective view depicting a PCB region 311-11 of panel 300(t0) during a SMT process that is used to mount passive components on rear rigid PCB section 116 of PCB region 311-11 according to block 220 of FIG. 3. Note that PCB region 311-11 (which corresponds to PCB substrate 111 of FIG. 1) is shown separate from panel 300(t0) for illustrative purposes, and is actually integrally formed with the remainder of panel 300(t0) during the process steps described below preceding singulation. During the first stage of the SMT process, lead-free solder paste (not shown) is printed on contact pads 119-1, which in the present example corresponds to SMT components 142, using custom made stencil that is tailored to the design and layout of PCB region 311-11. After dispensing the solder paste, the panel is conveyed to a conventional pick-and-place machine that mounts SMT components 142 onto contact pads 119-1 according to known techniques. Upon completion of the pick-and-place component mounting process, PCB panel 300(t0) is then passed through an IR-reflow oven set at the correct temperature profile. The solder of each pad on the PC board is fully melted during the peak temperature zone of the oven, and this melted solder connects all pins of the passive components to the finger pads of the PC board. FIG. 6 shows the resulting sub-assembled PCB panel 300(t1), in which each PCB region 311 (e.g., PCB region 311-11) includes passive components 142 mounted thereon by the completed SMT process.

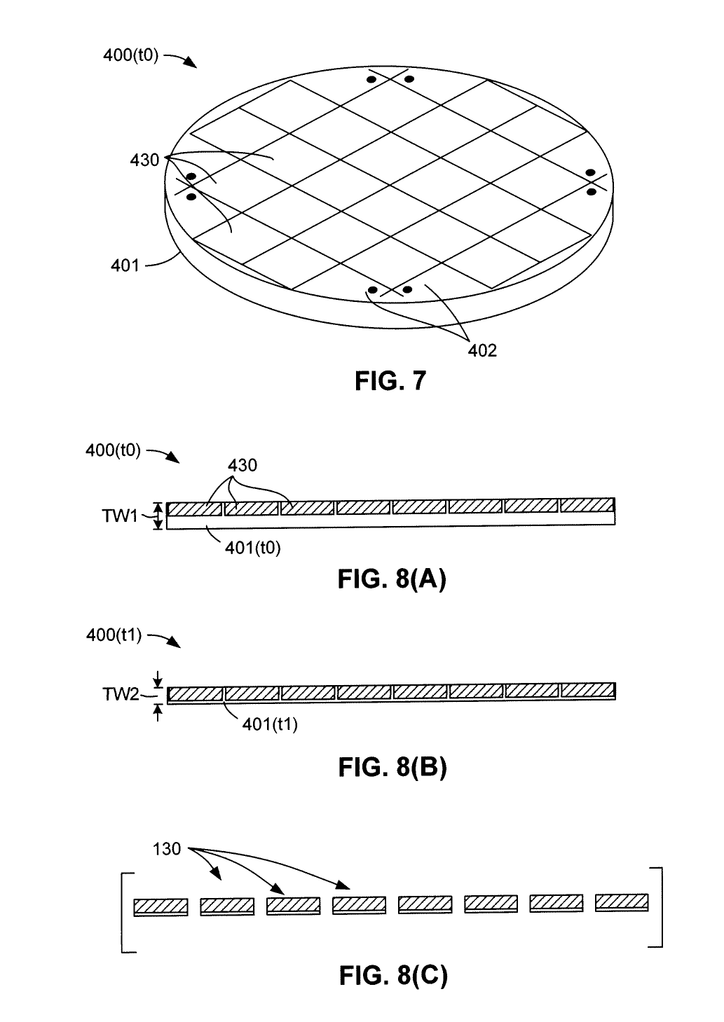

FIG. 7 is a simplified perspective view showing a semiconductor wafer 400(t0) procured or fabricated according to block 214 of FIG. 3. Wafer 400(t0) includes multiple ICs 430 that are formed in accordance with known photolithographic fabrication (e.g., CMOS) techniques on a semiconductor base 401. The corner partial dies 402 are inked out during die probe wafer testing, as are complete dies that fail electrical function or DC/AC parametric tests. In the example described below, wafer 400(t1) includes ICs 430 that comprise SD controller circuits. In a related procedure, a wafer (not shown) similar to wafer 400(t1) is produced/procured that includes flash memory circuits, and in an alterative embodiment, ICs 430 may include both SD controller circuits and flash memory circuits. In each instance, these wafers are processed as described herein with reference to FIGS. 8(A), 8(B) and 8(C).

As indicated in FIGS. 8(A) and 8(B), during a wafer back grind process according to block 242 of FIG. 3, base 401 is subjected to a grinding process in order to reduce the overall initial thickness TW1 of each IC 430. Wafer 400(t1) is first mount face down on sticky tape (i.e., such that base layer 401(t0) faces away from the tape), which is pre-taped on a metal or plastic ring frame (not shown). The ring-frame/wafer assembly is then loaded onto a vacuum chuck (not shown) having a very level, flat surface, and has diameter larger than that of wafer 400(t0). The base layer is then subjected to grinding until, as indicated in FIG. 8(B), wafer 400(t1) has a pre-programmed thickness TW2 that is less than initial thickness TW1 (shown in FIG. 8(A)). The wafer is cleaned using de-ionized (DI) water during the process, and wafer 400(t1) is subjected to a flush clean with more DI water at the end of mechanical grinding process, followed by spinning at high speed to air dry wafer 400(t1).

Next, as shown in FIG. 8(C), the wafer is diced (cut apart) along predefined border structures separating ICs 420 in order to produce IC dies 130 according to block 244 of FIG. 3. After the back grind process has completed, the sticky tape at the front side of wafer 400(t1) is removed, and wafer 400(t1) is mounted onto another ring frame having sticky tape provided thereon, this time with the backside of the newly grinded wafer contacting the tape. The ring framed wafers are then loaded into a die saw machine. The die saw machine is pre-programmed with the correct die size information, X-axis and Y-axis scribe lanes' width, wafer thickness and intended over cut depth. A proper saw blade width is then selected based on the widths of the XY scribe lanes. The cutting process begins dicing the first lane of the X-axis of the wafer. De-ionized wafer is flushing at the proper angle and pressure around the blade and wafer contact point to wash and sweep away the silicon saw dust while the saw is spinning and moving along the scribe lane. The sawing process will index to the second lane according to the die size and scribe width distance. After all the X-axis lanes have been completed sawing, the wafer chuck with rotate 90 degree to align the Y-axis scribe lanes to be cut. The cutting motion repeated until all the scribe lanes on the Y-axis have been completed.

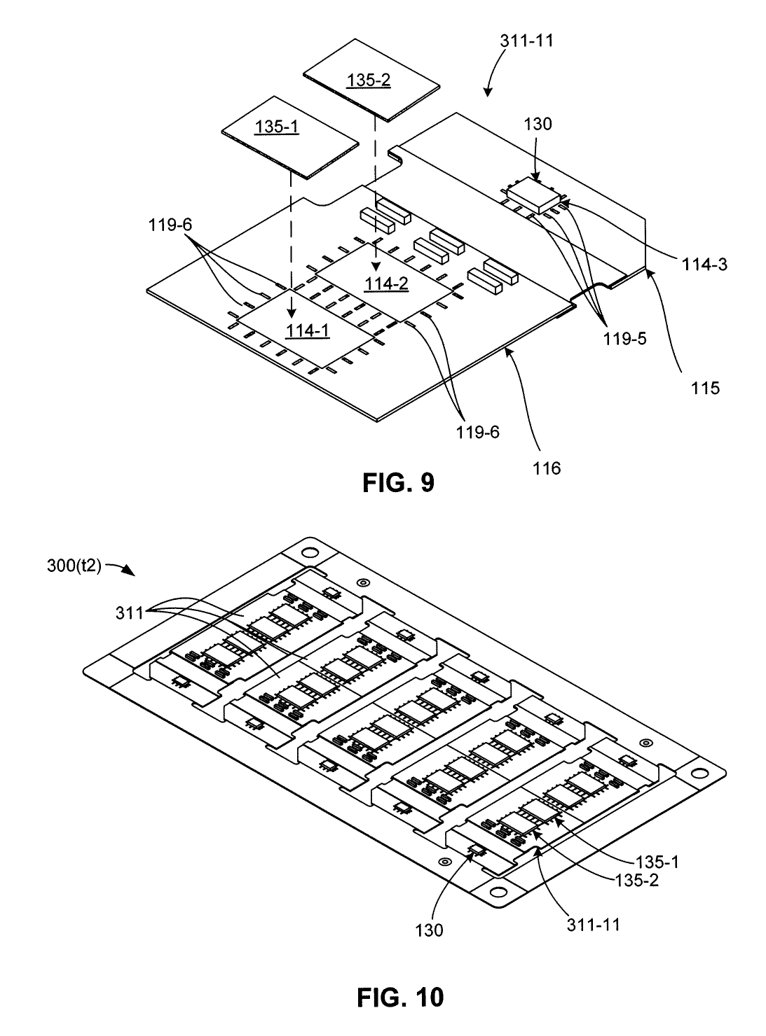

FIG. 9 is a perspective view depicting a die bonding process utilized to mount the controller IC dies 130 of FIG. 8(C) onto front rigid PCB section 115 and flash memory IC dies 135 onto rear rigid PCB section 116 of PCB region 311-11 according to block 246 of FIG. 3. The die bonding process is performed on PCB panel 300(t1) (see FIG. 6), that is, after completion of the SMT process. The die bonding process generally involves mounting controller IC dies 130 into lower surface region 114-3, which is located on front rigid PCB portion 115 and bordered by contact pads 119-5, and mounting flash IC dies 135-1 and 135-2 into lower surface regions 114-1 and 114-2, respectively, which are surrounded by contact pads 119-6. In one specific embodiment, an operator loads IC dies 130, 135-1 and 135-2 onto a die bonder machine according to known techniques. The operator also loads multiple PCB panels 300(t1) onto the magazine rack of the die bonder machine. The die bonder machine picks the first PCB panel 300(t1) from the bottom stack of the magazine and transports the selected PCB panel from the conveyor track to the die bond (DB) epoxy dispensing target area. The magazine lowers a notch automatically to get ready for the machine to pick up the second piece (the new bottom piece) in the next cycle of die bond operation. At the die bond epoxy dispensing target area, the machine automatically dispenses DB epoxy, using pre-programmed write pattern and speed with the correct nozzle size, onto the target areas 114-1 to 114-3 of each of the PCB region 311 of PCB panel 300(t1). When all PCBs region 311 have completed this epoxy dispensing process, the PCB panel is conveyed to a die bond (DB) target area. Meanwhile, at the input stage, the magazine is loading a second PCB panel to this vacant DB epoxy dispensing target area. At the die bond target area, the pick up arm mechanism and collet (suction head with rectangular ring at the perimeter so that vacuum from the center can create a suction force) picks up an IC die 130 and bonds it onto area 114-1, where epoxy has already dispensed for the bonding purpose, and this process is then performed to place IC die 135-1 and 135-2 into regions 114-2 and 114-3, respectively. Once all the PCB regions 311 on the PCB panel have completed die bonding process, the PCB panel is then conveyed to a snap cure region, where the PCB panel passes through a chamber having a heating element that radiates heat having a temperature that is suitable to thermally cure the epoxy. After curing, the PCB panel is conveyed into the empty slot of the magazine waiting at the output rack of the die bonding machine. The magazine moves up one slot after receiving a new panel to get ready for accepting the next panel in the second cycle of process. The die bonding machine will repeat these steps until all of the PCB panels in the input magazine are processed. This process step may repeat again for the same panel for stack die products that may require to stacks more than one layer of memory die. FIG. 10 is a top view showing PCB panel 300(t2) after the die bonding process is completed and controller IC 130 and memory IC die 135-1 and 135-2 are mounted onto each PCB region (e.g., PCB region 311-11).

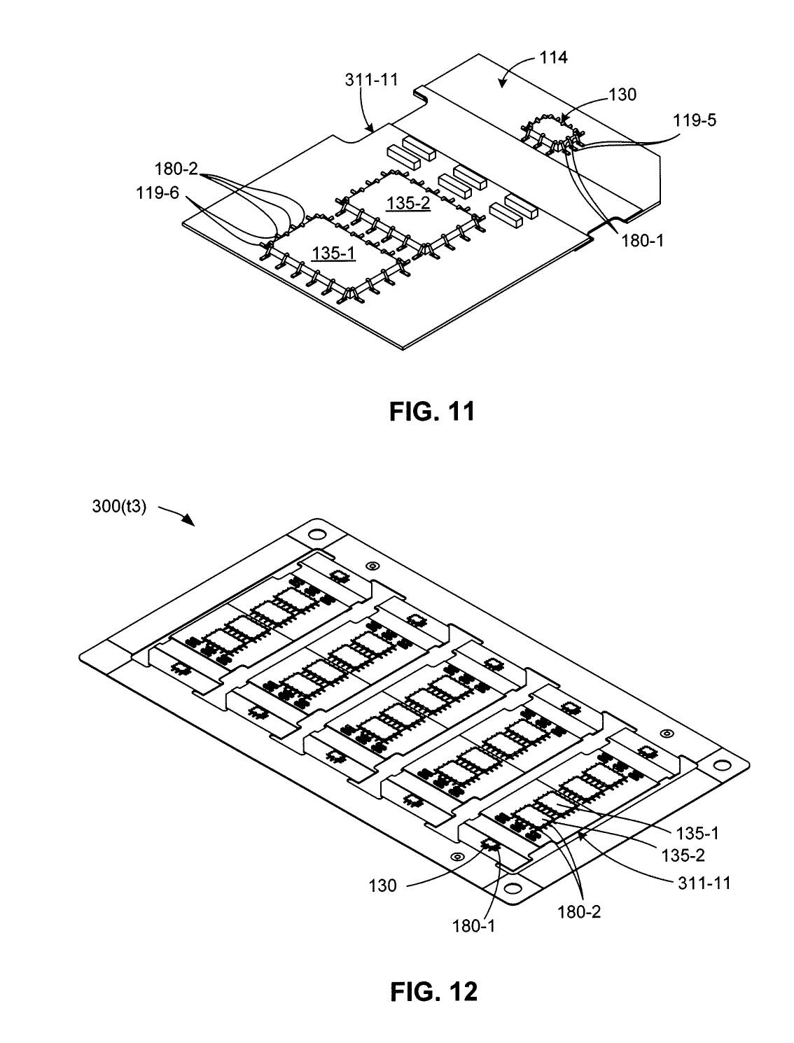

FIG. 11 is a perspective view depicting a wire bonding process utilized to connect the IC dies 130, 135-1 and 135-2 to corresponding contact pads 119-5 and 119-6 of PCB region 311-11, respectively, according to block 248 of FIG. 3. The wire bonding process proceeds as follows. Once a full magazine of PCB panels 300(t2) (see FIG. 10) has completed the die bonding operation, an operator transports the PCB panels 300(t2) to a nearby wire bonder (WB) machine, and loads the PCB panels 300(t2) onto the magazine input rack of the WB machine. The WB machine is pre-prepared with the correct program to process this specific SD device. The coordinates of all the ICs' pads 119-5 and 119-6 and PCB gold fingers were previously determined and programmed on the WB machine. After the PCB panel with the attached dies 130, 135-1 and 135-2 is loaded at the WB bonding area, the operator commands the WB machine to use optical vision to recognize the location of the first wire bond pad of the first controller die 130 of PCB region 311-11 on the panel. A corresponding wire 180-1 is then formed between each wire bond pad of controller die 130 and a corresponding contact pad 119-5 formed on PCB region 311-11. Once the first pin is set correctly and the first wire bond 180-1 is formed, the WB machine can carry out the whole wire bonding process for the rest of controller die 130, and then proceed to forming wire bonds 180-2 between corresponding wire bond pads (not shown) on memory die 135-1 and 135-2 and contact pads 119-6 to complete the wire bonding of memory die 135-1 and 135-2. Upon completing the wiring bonding process for PCB region 311-11, the wire bonding process is repeated for each PCB region 311 of the panel. For multiple flash layer stack dies, the PCB panels may be returned to the WB machine to repeat wire bonding process for the second stack in the manner described below. FIG. 12 is a top view showing PCB panel 300(t3) after the wire bonding process is completed.

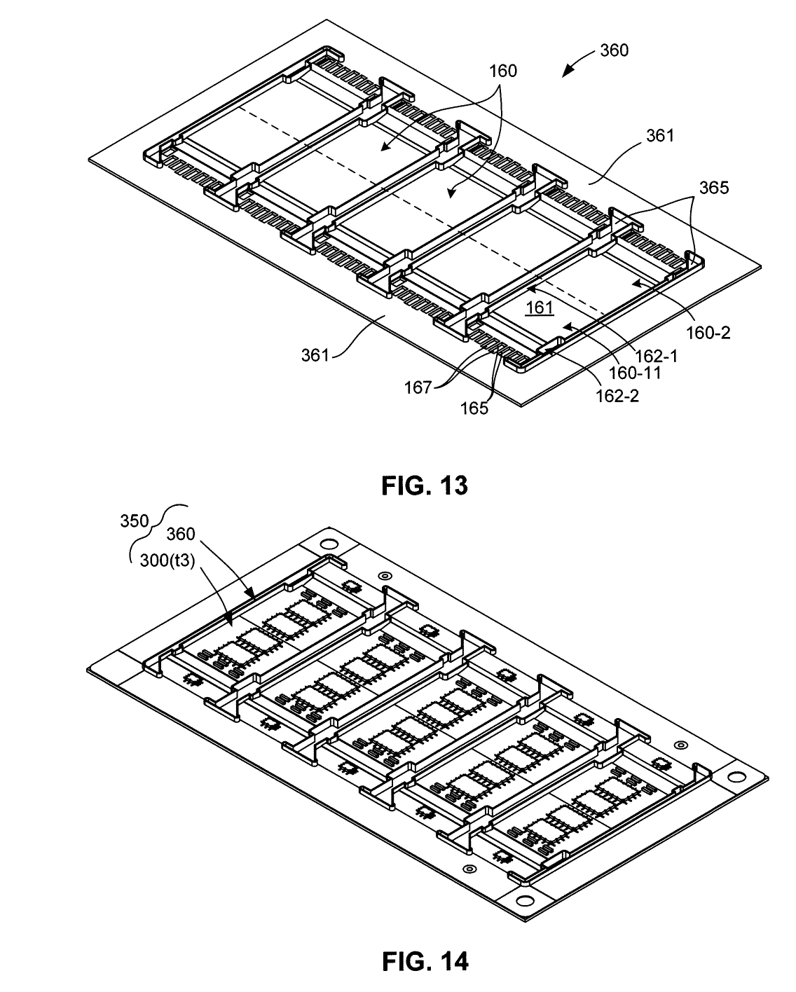

As indicated in FIGS. 13 and 14, after the wire bonding process is completed, an assembly 350 is formed by mounting PCB panel 300(t3) onto an upper housing panel 360 (shown in FIG. 13). As indicated in FIG. 13, upper housing panel 360 includes multiple upper housing portions 160 that are connected to end portions 361 and arranged in the same pattern as that of PCB regions 311 of PCB panel 300(t3). That is, each pair of associated upper housing portions 160 (e.g., upper housing portions 160-11 and 160-12) are connected together, supported between opposing end border rails 361, and separated from adjacent pairs of upper housing portions by elongated slots (openings) 365. Consistent with the description provided above, each upper housing portions 160 (e.g., upper housing portion 160-11) includes an upper wall 161, side walls 162-1 and 162-2 and ribs 165 that define openings 167. Prior to assembly an epoxy glue (not shown) is applied to the inside surface of upper housing portions 160, and then PCB panel 300(t3) is mounted as shown in FIG. 14 such that each PCB region 311 is received inside a corresponding upper housing portion 160. The resulting assembly 350 is shown in FIG. 14.

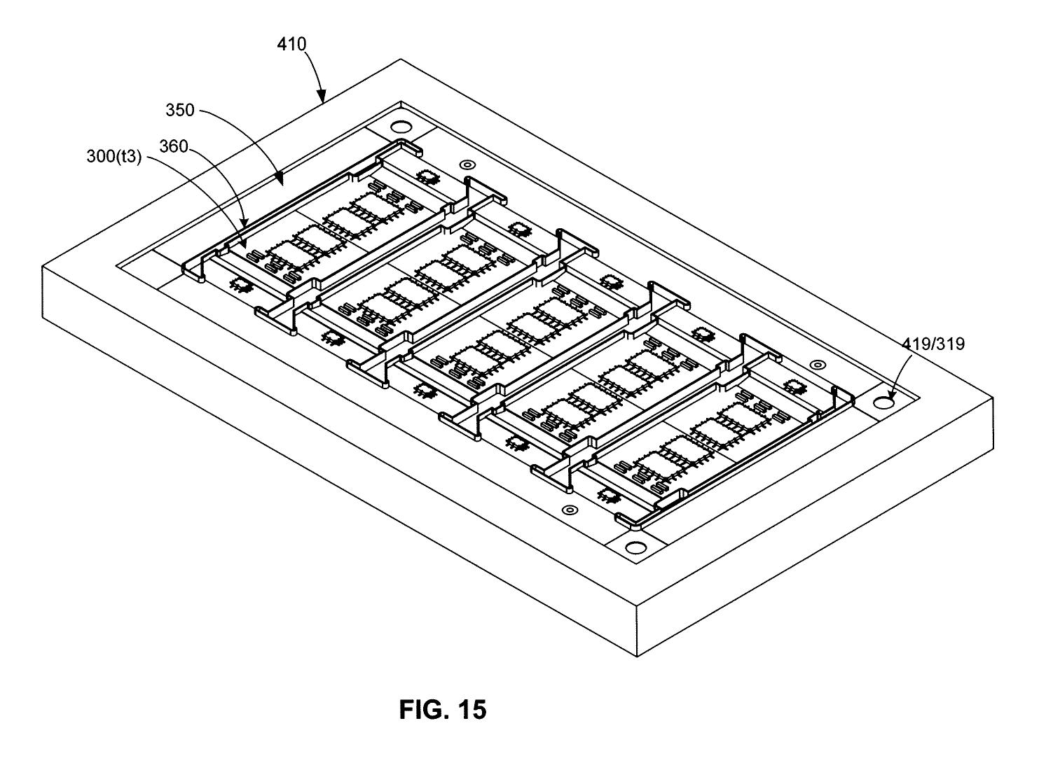

FIG. 15 is a top plan view depicting assembly 350, including PCB panel 300(t3) and upper housing panel 360, when it is mounted into lower molding die 410. Lower die 410 includes a shallow cavity surrounded by a peripheral surface that is shaped to receive assembly 350 (see FIG. 14) in the manner described below. In addition, lower die 410 includes three raised alignment poles 419 that are positioned to receive alignment holes 319 of PCB panel 300 (see FIG. 4(A)). Each alignment pole 419 provided on lower molding die 410 is received inside a corresponding alignment hole 319 of panel 300(t3), as shown in the rightmost corner of lower molding die 410, as shown in FIG. 15. Alignment poles 419 have a height that is not greater than the thickness of PCB panel 300.

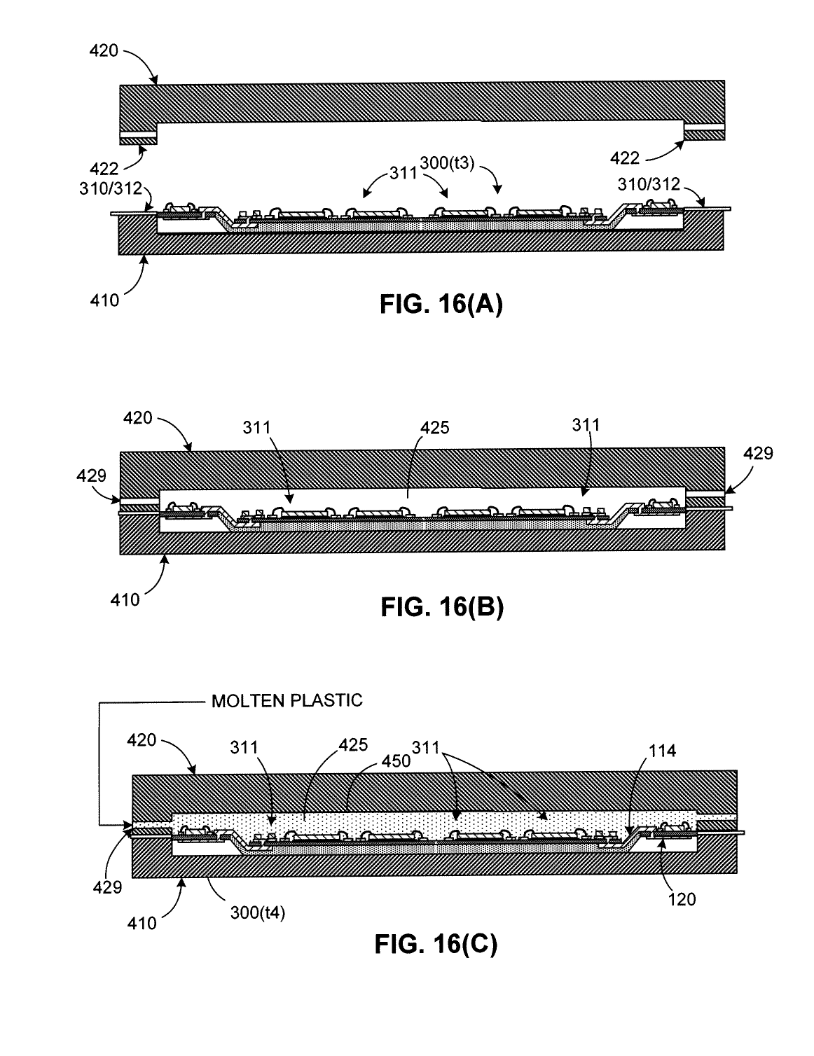

FIGS. 16(A), 16(B) and 16(C) are simplified cross-sectional side views depicting a molding process using molding dies 410 and 420. As indicated in FIG. 16(A) and 16(B), after panel 300(t3) is loaded into lower molding die 410, upper molding die 420 is positioned over and lowered onto lower molding die 410 until peripheral raised surface 422 presses against corresponding peripheral end/side portions 310/312 of PCB panel 300(t3) surrounding rigid-flex PCB regions 311, thereby forming substantially enclosed chambers 425 over each associated pair of rigid-flex PCB regions 311, as indicated in FIG. 16(B). Referring again to FIG. 16(B), in accordance with another aspect of the invention, a single run gate (channel) set 429 is provided for each associated pair of PCB regions 311 that facilitates the injection of molten plastic into chambers 425, as indicated in FIG. 16(C), whereby molded layer portions 450 are formed over lower surface 114 of each associated pair of rigid-flex PCB regions 311. From this point forward, the PCB panel is referred to as 300(t4).

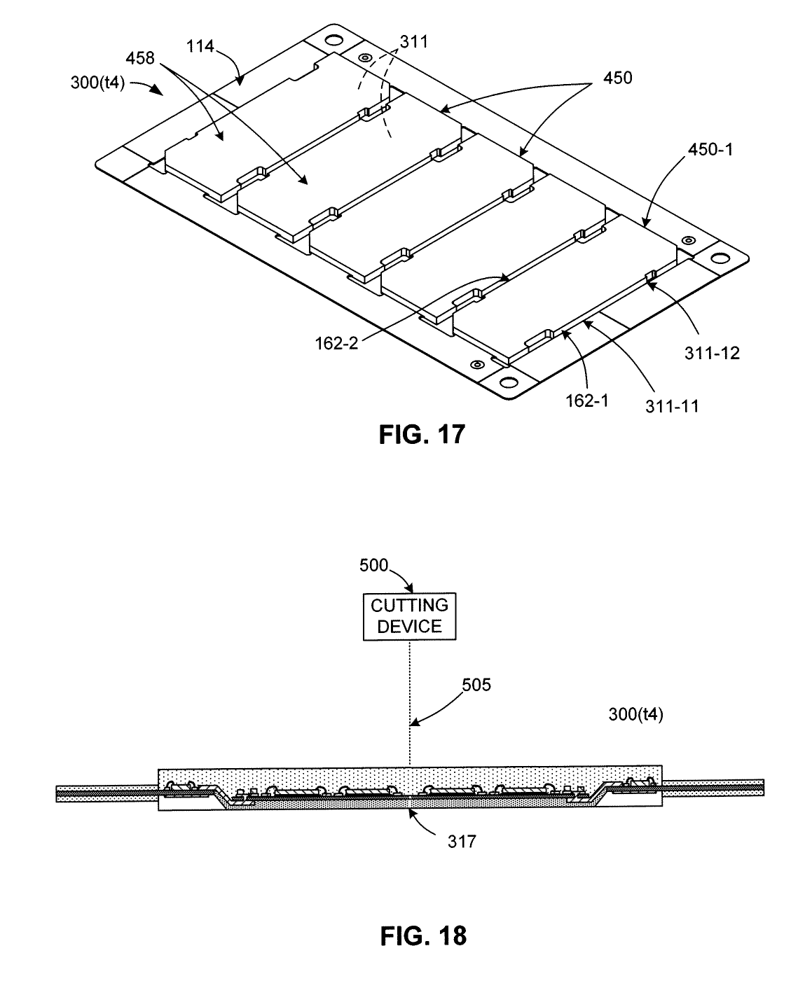

FIG. 16(C) depicts the molding process. Transfer molding is prefer here due to the high accuracy of transfer molding tooling and low cycle time. The molding material in the form of pellet is preheated and loaded into a pot or chamber (not shown). A plunger (not shown) is then used to force the material from the pot through channel sets 429 (also known as a sprue and runner system) into the mold cavity 425, causing the molten (e.g., plastic) material to form molded layer 450 that encapsulates all the IC chips and components, and to cover all the exposed areas of lower surface 114. Note that, because PCB 300(t4) is pressed against lower mold 420, no molding material is able to form on upper surface 112. The mold remains closed as the material is inserted and filled up all vacant areas of the mold die. During the process, the walls of upper die 420 are heated to a temperature above the melting point of the mold material, which facilitates a faster flow of material. The mold assembly remains closed until a curing reaction within the molding material is complete. A cooling down cycle follows the injection process, and the molding materials start to solidify and harden. Ejector pins push PCB panel 300(t4) (shown in FIG. 16(C) and 17) from the mold machine once the molding material has hardened sufficiently.

FIG. 17 is a perspective bottom view showing PCB panel 300(t4) after the plastic molding process of FIGS. 16(A) to 16(C) is completed. Panel 300(t4) includes five molded casing regions, wherein each molded casing region extends over lower surface 114 of each associated pair of PCB regions 311 (e.g., molded casing region 450-1 extends over PCB regions 311-1 and 311-2). Molded layer regions 450 are defined along each side by the side walls 162-1 and 162-2 of each upper housing portion 160, and have a substantially flat “lower” surface 458.

Referring again to block 260 of FIG. 3 and to FIG. 18, a subsequent processing step involves singulating (separating) the over-molded PCB panel to form individual SD devices by cutting said PCB panel and said molded layer using one of a saw or another cutting device 500 (e.g., a laser cutter or a water jet cutter), thereby separating said PCB panel into a plurality of individual SD devices. As shown in FIG. 18, PCB panel 300(t4) is loaded into a saw machine 500 that is pre-programmed with a singulation routine that includes predetermined cut locations defined by designated cut lines 317. A saw blade 505 is aligned to the first cut line as a starting point by the operator. The coordinates of the first position are stored in the memory of the saw machine. The saw machine then automatically proceeds to cut up (singulate) panel 300(t4).

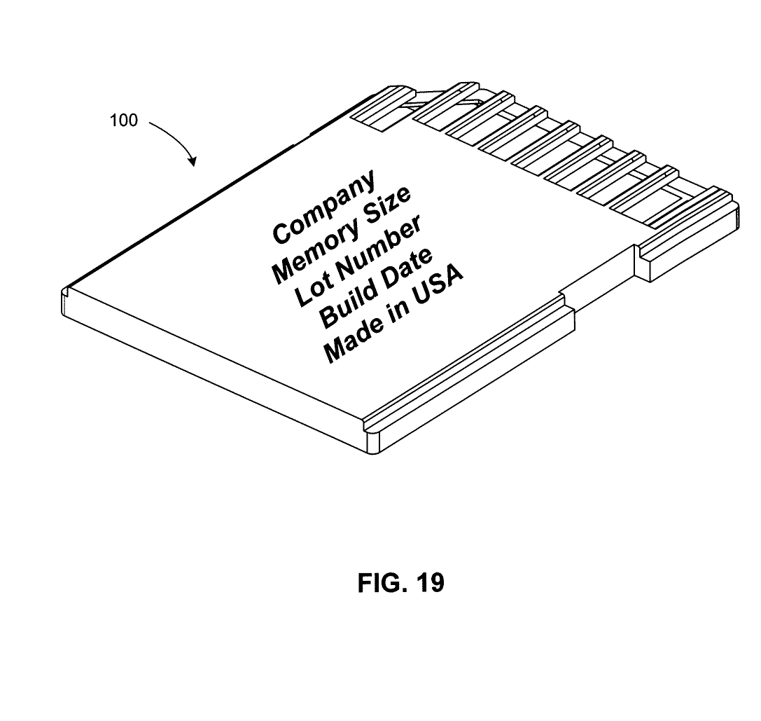

FIG. 19 is a perspective top view showing a SD device 100 after singulation, and further showing a marking process in accordance with block 270 of the method of FIG. 3. The singulated and completed SD devices 100 undergo a marking process in which a designated company's name/logo, speed value, density value, or other related information are printed on housing 150. After marking, SD devices 100 are placed in the baking oven to cure the permanent ink.

Referring to block 280 located at the bottom of FIG. 3, a final procedure in the manufacturing method of the present invention involves testing, packing and shipping the individual SD devices. The marked SD devices 100 shown in FIG. 19 are then subjected to visual inspection and electrical tests consistent with well established techniques. Visually or/and electrically test rejects are removed from the good population as defective rejects. The good memory cards are then packed into custom made boxes which are specified by customers. The final packed products will ship out to customers following correct procedures with necessary documents.

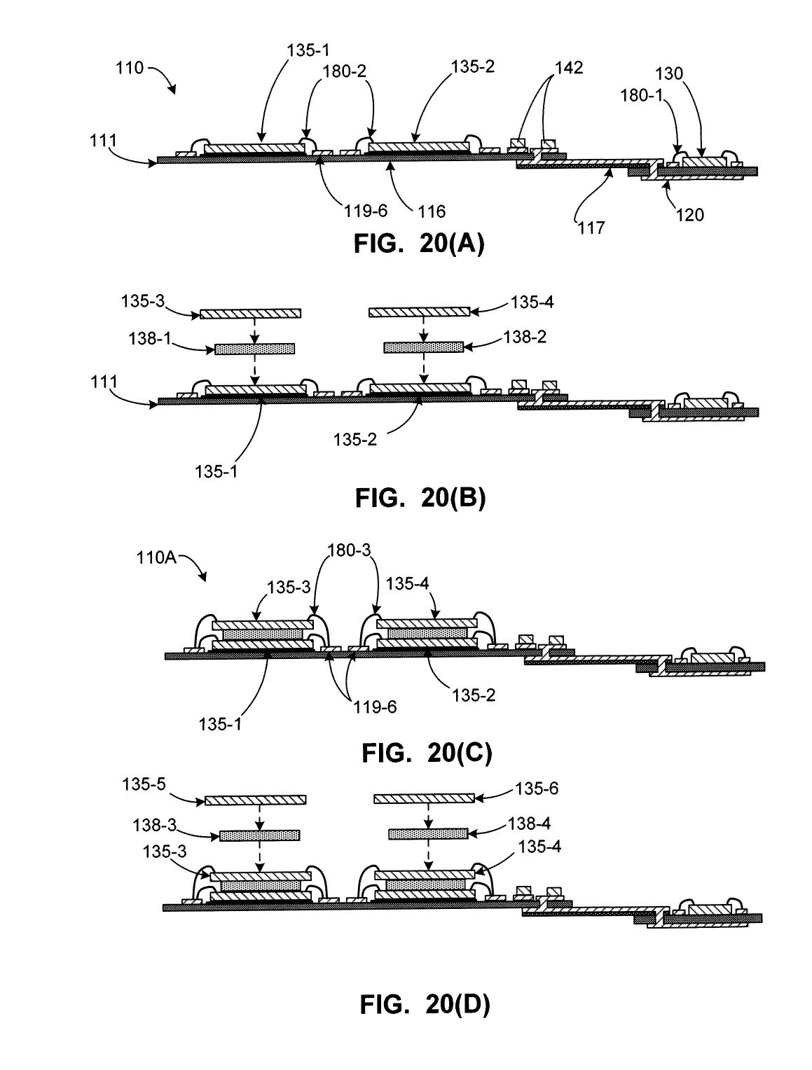

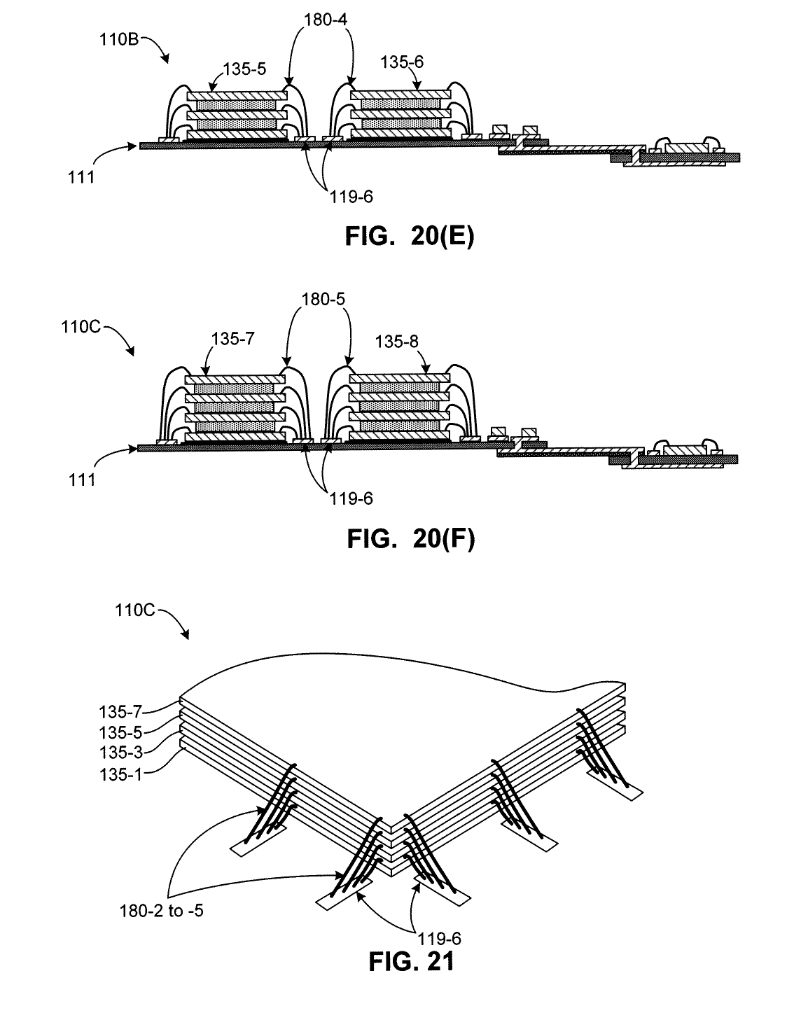

FIGS. 20(A)-20(F) are simplified cross-sectional side views showing a PCBA 110A during a stacked-device assembly process according to an alternative embodiment of the present invention. For high memory size SD flash memory cards, this stacked die process is necessary to pack more than a single layer of flash memory die in the same package. Due to space limitations associated with the standard SD package size, stacking flash memory dies one on top of the other is used to achieve the high memory size requirement. One or more iterations of looping between die bond and wire bond processes are used to achieve the desire memory size final SD memory card. This die bond and wire bond looping process is briefly illustrated in FIGS. 20(A) to 20(F). FIG. 20 (A) shows PCBA 110 after a first wire bonding process is performed to connect controller IC die 130 to rigid-flex PCB 111 using wire bonds 180-1, and to connect memory IC die 135-1 and 135-2 to rigid-flex PCB 111 using wire bonds 180-2, as described above with reference to PCB panel 300(t3) (see FIGS. 11 and 12). Next, as shown in FIG. 20(B), tape glue 138-1 and 138-2 is applied to the top of die 135-1 and 135-2, and a second layer of memory IC die 135-3 and 135-4 are respectively attached to die 135-1 and 135-2. As shown in FIG. 20(C), memory IC die 135-3 and 135-4 are then wire bonded to contact pads 119-6 by way of wire bonds 180-3, thereby forming intermediate PCBA 110A. Next, as shown in FIG. 20(D), tape glue 138-3 and 138-4 is applied to the top of die 135-3 and 135-4, and a third layer of memory IC die 135-5 and 135-6 are respectively attached to die 135-3 and 135-4. As shown in FIG. 20(E), memory IC die 135-5 and 135-6 are then wire bonded to contact pads 119-6 by way of wire bonds 180-4, thereby forming intermediate PCBA 110B. Finally, as shown in FIG. 20(F), tape glue is again applied, a fourth layer of memory IC die 135-7 and 135-8 are respectively attached, and then wire bonded to contact pads 119-6 by way of wire bonds 180-5, thereby forming PCBA 110C. FIG. 21 is a partial perspective view showing a portion of PCBA 110C of FIG. 20(F) including the multiple-layered die-stack made up of memory IC die 135-1, 135-3, 135-5 and 135-7, which are connected to associated contact pads 119-6 by way of wire bonds 180-2 to 180-5.

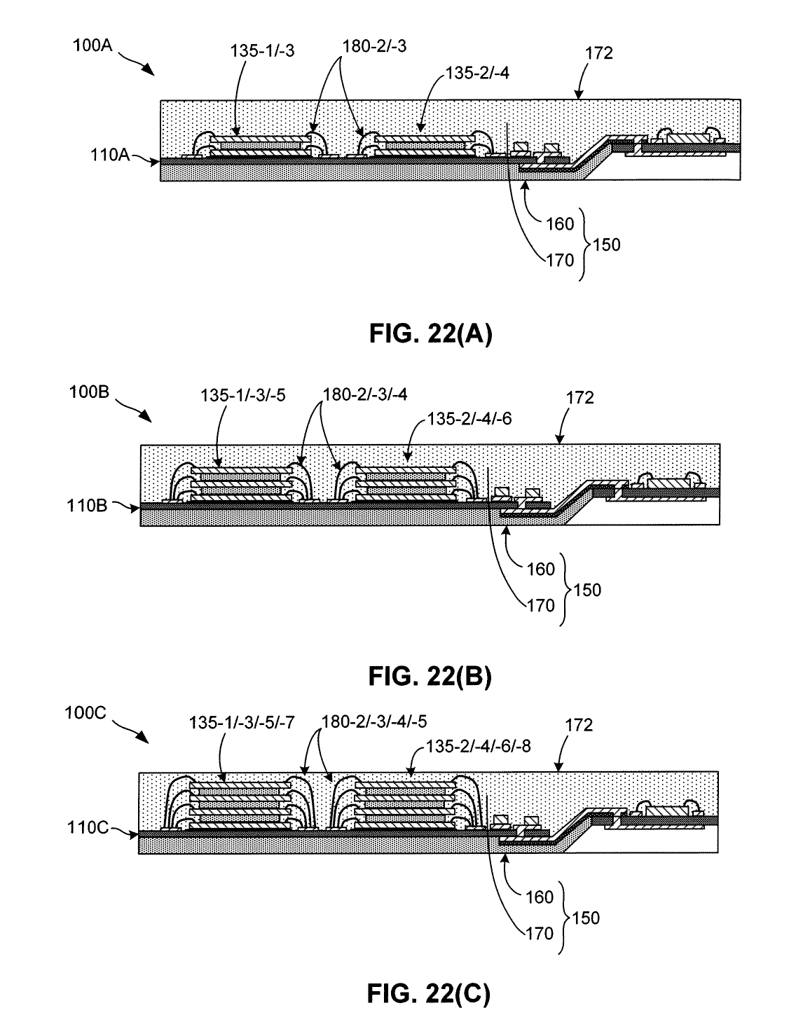

FIGS. 22(A), 22(B) and 22(C) are cross-sectional side views showing various SD devices 100A, 100B and 100C, respectively, which include different numbers of stacked memory devices according to alternative embodiments of the present invention. FIG. 22(A) shows a SD device 100A, which includes intermediate PCBA 110A (described above with reference to FIG. 20(C)) after the molding process in which housing 150 (including upper housing portion 160 and molded casing 170) disposed over memory IC die 135-1 to 135-4 and associated wire bonds 180-2 and 180-3. Similarly, FIG. 22(B) shows a SD device 100B, which includes intermediate PCBA 110B (described above with reference to FIG. 20(E)) after the molding process in which housing 150 (including upper housing portion 160 and molded casing 170) disposed over memory IC die 135-1 to 135-6 and associated wire bonds 180-2 to 180-4. Finally, FIG. 22(C) shows a SD device 100C, which includes PCBA 110C (described above with reference to FIG. 20(F)) after the molding process in which housing 150 (including upper housing portion 160 and molded casing 170) disposed over memory IC die 135-1 to 135-8 and associated wire bonds 180-2 to 180-5. Note that in each of SD devices 100A to 100C (FIGS. 20(A) to 20(C), upper surface 172 of molded casing 170 is disposed over the uppermost memory IC die and associated wire bonds, whereby the present invention facilitates the production of SD devices having a variety of storage capacities with minimal changes to the production process (i.e., simply changing the number of memory die layers changes the memory capacity).

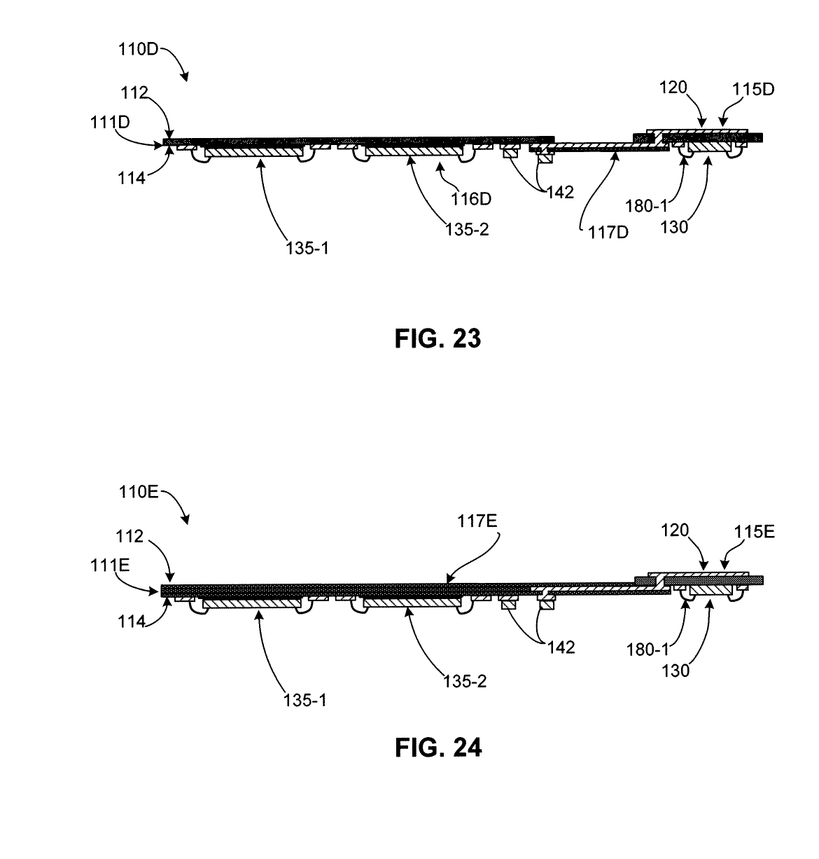

As set forth above, rigid-flex PCBs according to the present invention include at least one relatively rigid section and one relatively flexible section. In the first embodiment discussed above, e.g., with reference to FIG. 2 and 20(A), rigid-flex PCB 111 includes rigid PCB sections 115 and 116 that are connected by flexible PCB section 117, wherein rear rigid section 116 is connected to lower side 114 of flexible PCB section 117, and front rigid section 115 is connected to upper side 112 of flexible PCB section 117, thereby providing rigid-flex PCB 111 with a step or stair-case type construction in which the various components (e.g., controller IC die 130, memory IC die 135-1 and 135-2 and passive components 142) are mounted on the upper side 112 of rear rigid PCB section 116. In an alternative embodiment shown in FIG. 23, a PCBA 110D including an alternative rigid-flex PCB 111D in which both rigid PCB sections 115D and 116D are connected to upper side 112 of flexible PCB section 117D rigid-flex PCB 115D, thereby forming an “in-line” construction. Note that in this construction the various components (e.g., controller IC die 130, memory IC die 135-1 and 135-2 and passive components 142) are mounted on the lower side 112 of rear rigid PCB section 116D. FIG. 24 is a simplified cross-sectional side view showing yet another PCBA 110E including a rigid-flex PCB panel 111E having only a short rigid PCB section 115E located at the front end of rigid-flex PCB panel 111E, and an elongated flexible PCB section 117E on which the various components (e.g., controller IC die 130, memory IC die 135-1 and 135-2 and passive components 142) are mounted. In yet another alternative embodiment (not shown), instead of using a separate rigid PCB board structure (e.g., FR-4 or BT) to form short rigid PCB section 115E, rigid PCB section 115E may be formed by adding a stiffener (e.g., a polyimide stiffener) to a front section of the flexible cable used to construct flexible PCB section 117E.

Although the present invention has been described with respect to certain specific embodiments, it will be clear to those skilled in the art that the inventive features of the present invention are applicable to other embodiments as well, all of which are intended to fall within the scope of the present invention.

1. A memory card device comprising:
a printed circuit board assembly (PCBA) including:
a rigid-flex printed circuit board (PCB) having opposing first and second surfaces, the rigid-flex printed circuit board (PCB) including at least one rigid PCB section and at least one flexible PCB section connected to the at least one rigid PCB section, and a plurality of conductive traces forming signal paths between said at least one rigid PCB section and at least one flexible PCB section,
a plurality of metal contacts disposed on the second surface of the rigid-flex PCB and connected to corresponding conductive traces of said plurality of conductive traces,
at least one passive component mounted on the second surface of the rigid-flex PCB, and
at least one unpackaged integrated circuit (IC) die mounted on the second surface of the rigid-flex PCB; and
a housing including:
a plastic upper housing portion defining one or more openings, wherein the PCBA is mounted into the upper housing portion such that said plurality of metal contacts are exposed through said one or more openings, and
a molded casing comprising thermoset plastic formed over the second surface of the rigid-flex PCB such that said at least one passive component and said at least one IC die are encased by said thermoset plastic.

2. The memory card device according to claim 1, wherein the at least one rigid PCB section comprises one of FR-4 and Bismaleimide Triazine (BT), and the at least one flexible PCB section comprises a polyimide film.

3. The memory card device according to claim 1, wherein said rigid-flex printed circuit board (PCB) includes a first rigid PCB section, a second rigid PCB section, and a flexible PCB section connected between the first and second rigid PCB sections.

4. The memory card device according to claim 3,
wherein said plurality of metal contacts are disposed on the first rigid PCB section, and
wherein at least some of said at least one unpackaged IC die and said at least one passive component are mounted on the second rigid PCB section.

5. The memory card device according to claim 3,
wherein said plastic upper housing portion includes a upper wall having a first thickness, a plurality of ribs extending parallel to the upper wall and having a second thickness that is greater than the first thickness, and a step-like contour surface disposed between a planar inside surface of the upper wall and inside surfaces of said ribs, wherein each said opening is defined between an adjacent pair of said plurality of ribs, and
wherein said rigid-flex PCB is disposed in said plastic upper housing portion such that the first rigid PCB section is disposed against the inside surface of said ribs, the second rigid PCB section is disposed against the planar inside surface of said upper wall, and said flexible PCB section extends over said step-like contour surface.

6. The memory card device according to claim 5, wherein said at least one unpackaged IC die includes a controller IC die mounted on the first rigid PCB section and a plurality of memory IC dies mounted on the second rigid PCB section.

7. The memory card device according to claim 6, wherein said plurality of memory IC dies comprise a first memory IC die attached to said second rigid PCB section, and a second memory IC die stacked onto said first memory IC die, wherein each of said first and second IC dies are connected by associated first and second wire bonds to a contact pad disposed on said second rigid PCB section.

8. The memory card device according to claim 3, wherein a lower side of the first rigid PCB section is connected to an upper side of the flexible PCB section, and one of the upper side and the lower side of the second rigid PCB section connected to the flexible PCB section.

9. The memory card device according to claim 1,
wherein said rigid-flex printed circuit board (PCB) includes a rigid PCB section and a flexible PCB section connected to the rigid PCB section,
wherein the plurality of metal contacts disposed on the rigid PCB section, and said at least one passive component are mounted on the flexible PCB section.

10. The memory card device according to claim 9, wherein the rigid PCB section comprises a section of flexible cable and a stiffener.

11. The memory card device according to claim 1, wherein said memory card device comprises one of a SD device and a MMC device.

12. A method for producing a plurality of memory card devices, the method comprising:
producing a printed circuit board (PCB) panel including a plurality of rigid-flex PCBS, each rigid-flex PCB including at least one rigid PCB section and at least one flexible PCB section, wherein a plurality of contact pins are formed on a lower surface of said each at least one rigid PCB section;
attaching at least one passive component and at least one integrated circuit to an upper surface of each said rigid-flex PCB region;
mounting the PCB panel into a molding apparatus such that said upper surface of each said rigid-flex PCB region is pressed against an upper wall of a corresponding upper housing portion such that said contact pins are exposed through at least one opening defined in said upper housing portion;
forming a molded casing over the second surface of each rigid-flex PCB region such that said at least one passive component and said at least one IC die of each PCB region are covered by thermal set plastic; and
singulating said PCB panel by cutting said PCB panel such that the PCB panel is separated into said plurality of memory card devices, wherein each memory card device includes a rigid-flex PCB region, a corresponding said upper housing portion, and a corresponding said molded upper housing portion.

13. The method according to claim 12,
wherein producing said PCB panel comprises forming each said PCB region to include opposing first and second surfaces, a plurality of metal contacts disposed on the first surface, a plurality of first contact pads disposed on the second surface, a plurality of second contact pads disposed on the second surface, and a plurality of conductive traces formed on the PCB region such that each conductive trace is electrically connected to at least one of an associated metal contact, a first contact pad and a second contact pad; and
wherein attaching said at least one passive component and said at least one integrated circuit to each said PCB comprises:
attaching said at least one passive component to the first contact pads using a surface mount technique, and
attaching said at least one unpackaged integrated circuit (IC) die to the second contact pads using a chip-on-board technique.

14. The method of claim 13, wherein attaching said at least one passive component comprises:
printing a solder paste on said first contact pads;
mounting said at least one component on said first contact pads; and
reflowing the solder paste such that said at least one component is fixedly soldered to said first contact pads.

15. The method of claim 13, further comprising grinding a wafer including said at least one IC die such that a thickness of said wafer is reduced during said grinding, and then dicing said wafer to provide said at least one IC die.

16. The method of claim 15, wherein attaching at least one IC die comprises bonding a first IC die to the second surface of the PCB and wire bonding the first IC die to said second contact pad.

17. The method of claim 16, wherein attaching at least one IC die further comprises bonding a second IC die to the first IC die, and wire bonding wire bonding the second IC die to a third contact pad.

18. The method according to claim 12, wherein forming said molded upper housing portion comprises disposing said PCB panel and said associated upper housing portions into a first molding die, said first molding die comprises a plurality of alignment poles, and wherein disposing said PCB panel comprises operably engaging said alignment poles into corresponding alignment holes defined in said PCB panel.

19. The method according to claim 12, wherein singulating said PCB panel after forming said single-piece molded layer comprises cutting said PCB panel and said molded layer using a saw, whereby PCB substrate is separated from said PCB panel, and a molded is separated from said molded layer.

20. The method according to claim 12, wherein said memory card devices comprise one of SD devices and MMC devices.
